(19) United States
(12) Patent Application Publication
(10) Pub. No.: US 2018/0044778 A1
(43) Pub. Date: Feb. 15, 2018

(54) SPUTTERING TARGET HAVING REVERSE BOWNG TARGET GEOMETRY

(71) Applicant: Tosoh SMD, Inc., Grove City, OH (US)

(72) Inventors: Robert S. Bailey, Grove City, OH (US); Junhai Yan, Grove City, OH (US); Melvin Kirk Holcomb, Grove City, OH (US); Alexander Leybovich, Grove City, OH (US)

(21) Appl. No.: 15/553,736

(22) PCT Filed: Feb. 23, 2016
(86) PCT No.: PCT/US2016/019085

§ 371 Date: Aug. 25, 2017

Related U.S. Application Data
(60) Provisional application No. 62/126,911, filed on Mar. 2, 2015.
(60) Provisional application No. 62/182,002, filed on Jun. 19, 2015.

(51) Int. Cl. C23C 14/34; H01J 37/34; C22C 9/00

(52) U.S. Cl. CPC C23C 14/3407; C22C 9/00; H01J 37/3408; H01J 37/3423; H01J 37/3426; H01J 37/3491

(57) ABSTRACT

Generally planar sputter targets having a reverse bow surface (i.e., convexity) facing the magnets in a magnetron assembly is provided. Methods of making Cu and Cu alloy targets are provided including an annealing step performed at temperatures of from 1100-1300 F for a period of about 1-2 hours. Targets made by the methods have increased grain sizes on the order of 30-90 microns.

### CROSS REFERENCE TO RELATED APPLICATIONS

This application claims the priority benefit of U.S. Provisional Patent Application Ser. No. 62/126,911 filed Mar. 2, 2015 and U.S. Provisional Patent Application Ser. No. 62/182,002 filed Jun. 19, 2015.

### FIELD OF INVENTION

The present application pertains to sputter targets that are provided with a convex surface facing the magnets in a conventional magnetron target assembly. Additionally, methods are provided to increase the grain growth of Cu and Cu alloy targets to reduce operating discharge voltage of the target.

### BACKGROUND OF THE INVENTION

Targets having planar surfaces facing the magnets in a conventional magnetron assembly typically bow, during usage, toward the vacuum chamber. This condition leads to increased voltage discharge of the target. In some cases, if the discharge voltage reaches the compliance level of the power supply, power cannot be maintained. This “compliance” level is sometimes referred to as the sputter system threshold.

A somewhat similar problem may occur in conventional Cu and Cu alloy targets. Typically, these targets are produced to have a very fine grain size on the order of 20 microns or less for pure Cu and under 15 microns for Cu alloys. Such targets can create concerns if they sputter at high discharge voltage.

### SUMMARY OF THE INVENTION

In one aspect of the invention, a generally planar sputter target is provided that has an initial reverse bow in the form of a convex surface. This reverse bow exhibits a percent bowing of greater than 0.04%. The reverse bow is adapted for continued bowing during sputtering.

The percent bowing can be calculated as follows:

x/y×100=% target bowing

wherein x=the distance (mm) between a planar target surface and bowed target surface measured at the central axis of target;
wherein y=target diameter (mm).

In other embodiments, the reverse bowing has a percent bowing in the range of between about 0.04%-0.25%. In some cases, the target may comprise Cu, Al, Ti, or Ta, or alloys of these elements.

In some exemplary embodiments, the sputter target may be a monolithic sputter target, or in other embodiments, the sputter target may be bonded to a backing plate via diffusion bonding, explosion bonding, or via a mechanical interlocking type bond.

Other embodiments of the invention are directed to a sputter target that is adapted for reception in a sputtering chamber of the type having a substrate that is to be coated with material sputtered from the target. A magnet source is positioned proximate the target for producing a magnetic field within the chamber. The sputter target has a sputter surface from which material is sputtered onto the desired substrate, and the sputter target has an opposing surface proximate the magnet source. The opposing surface of the target may, in certain embodiments, include a convex surface facing the magnet source. In other embodiments, the sputter surface of the target may comprise a generally concave shape.

In other embodiments of the invention, a Cu or Cu alloy sputtering target is provided that has grain sizes on the order of about 30-90 microns.

Certain aspects of the invention are related to methods for making a Cu or Cu alloy sputtering target from Cu or Cu alloy raw materials. The method may comprise, for example, the steps of
a) melting and casting said Cu or Cu alloy raw materials to form an ingot;
b) thermomechanically working said ingot to form a plate;
c) annealing said plate at a temperature of about 1100-1300° F. for a period of about 1-2 hours to form an annealed plate; and
d) surface treating said annealed plate by a surface treatment process selected from the group consisting of grinding, polishing, honing, and machining to provide a desired surface and shape for said sputter target, wherein said target has an average grain size of from about 30-90 microns.

The Invention will be further explained in conjunction with the appended drawings and following detailed description.

### BRIEF DESCRIPTION OF THE DRAWINGS

FIG. 1 is a schematic illustration of a magnetron sputtering assembly shown in combination with a bowed target in accordance with the invention; and

FIG. 2 is a schematic cross section of one half of a bowed target in accordance with the invention compared with a conventional target configuration wherein the conventional target contour is shown in phantom.

### DETAILED DESCRIPTION

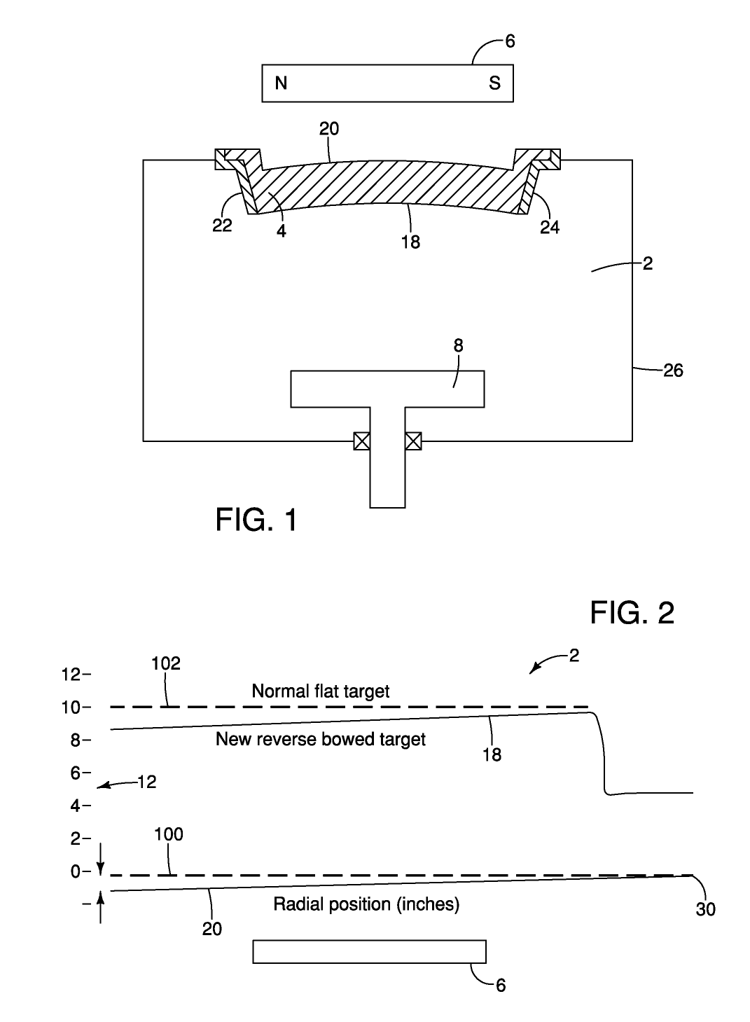

With reference to the figures, there is shown in FIG. 1 a schematic cross section of a cathodic sputtering chamber 2. The chamber defines a sealed housing defined by the enclosure 26. Typically, a vacuum is drawn on the chamber and an electrical voltage is impressed across the chamber such that sputter target 4 is provided with a negative voltage and a positive voltage is impressed upon a portion of the chamber (or chamber shield—not shown) proximate the substrate (e.g., wafer) pedestal 8. A working gas such as Ar is admitted to the chamber. Seals 22, 24 are provided surrounding the target at its mount within the enclosure 26.

When the argon is admitted into the chamber, the DC voltage applied between the negatively charged target and the positively charged portion of the chamber, the Ar is ignited into a plasma with the positively charged argon ions attracted to the negatively charged target 4. Target 4 may be composed of Cu, Al, Ti, or Ta, or alloys of these metals. The ions strike the target with substantial energy causing the target atoms to be sputtered from target sputter surface 18 to a wafer or the like positioned on pedestal 8, thereby forming a film of target material onto the desired substrate such as a wafer or the like.

The magnets 6 positioned to the rear of the target produce a magnetic field within the chamber in proximity to the magnets to trap electrons and form a high density plasma region within the chamber adjacent the magnets. In practice, the magnets are usually rotated about the center of the target.

The invention will be further explained in conjunction with FIG. 2 which is a schematic cross section view of one half of the target shown in FIG. 1. Here, the central axis of the target is defined by the Y axis with the X axis denoting radial position of the target surfaces. It is noted that actual targets will be represented by a symmetrical combination of two target halves of the type shown in this figure with the Y axis extending as a central axis through the target.

The side 20 of the target facing the magnets 6 is provided with a bowed cross section defining a convex shape along this surface 20. As measured relative to a plane defined by the radial edges 30 of the target surface 20, at the central axis, this convexity, at its pinnacle, in one embodiment, exceeds a threshold of about 0.2-0.4 mm. In other embodiments, the target has a bow of about 0.4-1 mm. Although applicant is not to be bound to any particular theory of operation, it is thought that bowing of the magnet side 20 of the target (i.e., a convex geometry facing the magnets) has a significant effect on the plasma discharge voltage when sputtering a planar sputter target under standard conditions. Most targets naturally bow into the vacuum chamber during sputtering. It is possible to change the direction that a target bows by altering the initial shape. By providing an initial outward bow on the magnet side of the target, the target will continue to bow in this outward direction as it heats up and expands (during sputtering). Computer modeling has shown that if an initial outward bow exceeds a threshold (˜0.2-0.4 mm), the target will continue to bow outward during sputtering.

An outward bowing target will sputter with low discharge voltage (under the same conditions) compared to an inward bowing target. Lower discharge voltage can be desirable in certain sputtering systems where plasma impedance issues limit target life. An outward bowing target will be more stable during life, compared to an inward bowing target, in that the amount of bow does not continued to increase throughout target life.

Some conventional diffusion bonded targets have been made which bow outward, due to stress relief during the initial stages of sputtering. In these conventional cases, the targets are initially flat. The outward bowing direction is the result of stress relief altering the initial geometry to one that favors outward bowing. The purpose of this invention is to provide an initial shape (in a low stress assembly—such as monolithic) which favors the outward bowing direction along the magnet side 20 of the target. Such a design would be easier to control and could be applied to many different assembly methods (monolithic, diffusion bonded, mechanical bonded, etc.).

As shown, outward bowing along the magnet side 20 positions this surface closer to the magnetron source which will create a stronger magnetic field at the surface of the target and allow the target to sputter with a lower discharge voltage. In certain cases, if the discharge voltage reaches the compliance limit of the power supply, power cannot be maintained. An outward bowing target will help avoid that failure mode.

With further reference to FIG. 2, the contour of a conventional planar target is shown in phantom at 100, 102. Surface 100 of the conventional target facing the magnets 6 is generally planar. This contrasts with target surface 20 of the invention showing a convex face or surface facing the magnets and the distance between conventional surface 100 and surface 20 at the center of the target or pinnacle of the outward bowing of surface 20, as shown by the arrows, exceeds a threshold of 0.2 mm-0.4 mm. In some instances, this distance (as shown by the arrows) is from about 0.4-1 mm.

In some exemplary embodiments, target 4 is adapted to sputter coat a wafer on pedestal 8 wherein the wafer is of circular shape having a diameter of about 300 mm. Target 4 may, in some embodiments, have a circular shape with a diameter of about 450 mm. In some embodiments, the bowing of surface 20 then as measured at the central axis of the target (i.e., the y axis in FIG. 2) is equal to or exceeds the diameter of the target by 0.04% or greater. In other embodiments, the convex bowing of surface 6, as measured along the central axis of the target (see y axis in FIG. 2) is greater than 0.08% of the target diameter. Other embodiments of the invention have outward bowing/target diameter ranges of between about 0.04%-0.25% or 0.08% to 0.25%. These are referred to in terms of “outward bowing %”.

Stated differently, the percent bowing can be calculated as follows:

x/y×100=% target bowing

wherein x=the distance (mm) between a planar target surface and bowed target surface measured at the central axis of target;
wherein y=target diameter (mm).

In other embodiments of the invention, the target sputtering surface side 18 is provided with a concave surface. In certain embodiments, this concavity is a mirror image of the convexity existing along the magnet side 20. The concavity along the sputtering surface side 18 of the target helps to force bowing of the target toward the magnet source.

With regard to the inward (concave surface shape) bowing of surface 18, the inward percent distance may be within the same ranges as previously denoted for the convex surface 20. For example, the inward percent bowing for surface may be greater than 0.04%, or greater than 0.08% in some embodiments. In other embodiments, the inward percent bowing may be within the range of about 0.04-0.25%. In one embodiment of inward percent bowing of surface 18 is the same as the outward percent bowing of the convex surface 20.

As shown, targets in accordance with the invention are adapted for use in sputter chambers, positioned in the chamber, intermediate the desired substrate and the magnet source. In preferred embodiments, the target is a one piece assembly without separate backing plate member. Such targets may be referred to as monolithic in design. Other embodiments of the invention envision target/backing plate configurations where the target is bonded to a backing plate via bonding techniques such as diffusion, explosion bonding, or mechanical interlocking type bonds.

In another aspect of the invention, a copper (or copper alloy) sputtering target is provided that sputters with lower discharge voltage compared to conventional targets. Lower discharge voltage can be desirable in certain sputtering systems where plasma impedance issues limit target life. If the voltage increases to the limit of the power supply, then power cannot be maintained.

Conventional Cu targets are produced to have a very fine grain size, typically under 20 microns for pure copper and under 15 microns for copper alloys. As part of this invention, it has been experimentally determined that annealing Cu sputtering targets to grow the grain size above 30 microns can reduce the sputtering discharge voltage. One exemplary grain size range is from about 30 to about 90 microns. The voltage reduction is the result of an increase in the secondary electron yield associated with the microstructure changes created by the elevated temperature annealing.

As the target heats up and expands during sputtering, it will typically bow into the sputtering chamber which increases the distance from the magnetron source magnets. This bowing motion decreases the magnetic field at the surface of the target which results in higher voltage. A second part of this invention is to provide a target with an initial shape which is bowed toward the magnets. This helps to reduce the amount of bow away from the magnets during sputtering. Conventional targets are flat.

Preliminary testing has produced test targets that have achieved voltage reductions of 30 to 40 volts by annealing to achieve >30 micron grain size. At this point, we have also achieved 30-40 volt reductions by providing targets that have an initial reverse bow geometry.

Annealing temperatures are a function of the Cu alloy composition. For the Cu 0.5 wt % Mn targets tested at this point, annealing temperatures of about greater than 1100° F. for two hours have proven effective. Preferred annealing temperatures are on the order of about 1100 to 1292° F.

In order to form the Cu targets and Cu alloy targets of the invention, the raw materials, i.e., Cu and alloying metal, are melted and cast to form an ingot. The ingot is subjected to thermo-mechanical processing such as forging and cold rolling in order to form a plate. The plate is then subjected to an annealing step conducted at temperatures of about 1100-1300° F. for a period of 1-2 hours. Afterward, the target is subjected to surface treatments such as grinding, polishing, honing, machining, etc. The thus surface treated plate may be used by itself as a monolithic target, or it may be bonded to a backing plate via conventional techniques such as diffusion bonding, explosion bonding, or mechanical interlocking type bonding. In some aspects, this mechanical interlocking type bonding process may be conducted at room temperature. Suitable mechanical bonding techniques are disclosed in U.S. Pat. Nos. 6,749,103; 6,725,522; and 7,114,643, all incorporated herein by reference. All of these patents disclose mechanical, interlocking bonds formed along interfacial mating surfaces of the target and backing plate.

As to the alloying elements that may be present, along with the Cu, these may, in some embodiments, include 1) Co, Cr, Mo, W, Fe, Nb, or V. In other embodiments, the alloying element may be 2) Sb, Zr, Ti, Ag, Au, Cd, In, As, Be, B, Mg, Mn, Al, Si, Ca, Ba, La, and Ce. Mixtures of any of the alloying elements in groups 1) and 2) may also be noted as exemplary. In most cases, the alloying elements will be present in an amount (atomic %) of 30% or less.

Although this invention has been described in connection with specific forms thereof, it will be appreciated by one reading the preceding description of the present invention that a wide variety of equivalents may be substituted for those specific elements and steps of operation shown and described herein, that certain features may be used independently of other features, all without departing from the spirit and scope of this invention as defined in the appended claims.

1. A generally planar sputter target that has an initial reverse bow in the form of a convex surface exhibiting a percent bowing of greater than 0.04%, said reverse bow adapted for continued bowing during sputtering.

2. A sputter target as recited in claim 1 wherein said percent bowing is between about 0.04%-0.25%.

3. A sputter target as recited in claim 1 composed of Cu, Al, Ti, or Ta, or alloys of these elements.

4. A sputter target as recited in claim 3 wherein said sputter target comprises Cu or Cu alloy, and wherein said sputter target is a monolithic sputter target.

5. A sputter target as recited in claim 3 in combination with a backing plate, said sputter target and said backing plate bonded together via a mechanical interlocking bond.

6. A sputter target adapted for reception in a sputtering chamber of the type having a substrate that is to be coated with material sputtered from said target, and a magnet source proximate said target for producing a magnetic field within said chamber, said sputter target having a sputter surface from which said material is sputtered onto said substrate and an opposing surface proximate said magnet source, said opposing surface comprising a convex surface facing said magnet source.

7. A sputter target as recited in claim 6 wherein said target is a generally planar monolithic target.

8. A sputter target as recited in claim 6 wherein said sputter surface of said target comprises a generally concave shape.

9. A sputter target as recited in claim 6 wherein said convex surface has a percent bowing of greater than 0.04%.

10. A sputter target as recited in claim 6 wherein said percent bowing is between about 0.04% and 0.25%.

11. A sputter target as recited in claim 6 wherein said sputter target is composed of Cu, Al, Ti, or Ta, or alloys of these elements.

12. A sputter target as recited in claim 11 wherein said sputter target is composed of Cu or Cu alloy.

13. A sputter target as recited in claim 6 in combination with a backing plate, said sputter target and said backing plate bonded together by a mechanical interlocking bond.

14. A sputter target as recited in claim 6 in combination with a backing plate, said sputter target and said backing plate bonded together by a diffusion bond or explosion bond.

15. A planar sputter target of Cu or Cu alloy having grain sizes of from about 30-90 microns.

16. A method of making a Cu or Cu alloy sputter target from Cu or Cu alloy raw materials comprising:
a) melting and casting said Cu or Cu alloy raw materials to form an ingot;
b) thermomechanically working said ingot to form a plate;
c) annealing said plate at a temperature of about 1100-1300° F. for a period of about 1-2 hours to form an annealed plate; and
d) surface treating said annealed plate by a surface treatment process selected from the group consisting of grinding, polishing, honing, and machining to provide a desired surface and shape for said sputter target, wherein said target has an average grain size of from about 30-90 microns.

17. A sputter target adapted for reception in a sputtering chamber of the type having a substrate that is to be coated with material sputtered from said target, and a magnet source proximate said target for producing a magnetic field within said chamber, said sputter target having a sputter surface from which said material is sputtered onto said substrate and an opposing surface proximate said magnet source, said opposing surface comprising a convex surface facing said magnet source, said sputter target being made by the process of claim 16.
